(19) United States
(12) Patent Application Publication
(10) Pub. No.: US 2014/0124029 A1
(43) Pub. Date: May 8, 2014

(54) CONDUCTING SUBSTRATE FOR A PHOTOVOLTAIC CELL

(71) Applicants: Frederic Clabau, Paris (FR); Mathieu Urien, Fontenay sous Bois (FR); Charles Leyder, Paris (FR); Gerard Ruitenberg, Herzogenrath (DE); Delphine Dupuy, Massy (FR)

(72) Inventors: Frederic Clabau, Paris (FR); Mathieu Urien, Fontenay sous Bois (FR); Charles Leyder, Paris (FR); Gerard Ruitenberg, Herzogenrath (DE); Delphine Dupuy, Massy (FR)

(73) Assignee: SAINT-GOBAIN GLASS FRANCE, Courbevoie (FR)

(21) Appl. No.: 14/129,191

(22) PCT Filed: Jun. 25, 2012
(86) PCT No.: PCT/FR2012/051450

§ 371 Date: Dec. 24, 2013

(30) Foreign Application Priority Data
Jun. 27, 2011 (FR) 1155712

(51) Int. Cl. H01L 31/0224

(52) U.S. Cl. CPC H01L 31/022425
USPC 136/256

(57) ABSTRACT

A conducting substrate includes a dielectric substrate having alkali ions, an electrode coating having a molybdenum-based layer on the substrate, and a stack of several layers between the substrate and the electrode coating. The stack comprises a first layer impermeable to alkali on the substrate, a layer for retention of alkali on the first layer impermeable to alkali and made of another material, and a second layer impermeable to alkali on the layer for retention of alkali and made of a material other than the layer for retention of alkali. The ratio of the thickness of the layer for retention of alkali to the first layer impermeable to alkali is equal to 2 or more.

The invention relates to the field of photovoltaic cells, more particularly to the field of molybdenum-based conducting substrates used to manufacture thin-layer photovoltaic cells.

Specifically, in a known way, some thin-layer photovoltaic cells, referred to as second generation, use a molybdenum-based conducting substrate coated with a layer of absorbing agent, generally made of copper Cu, indium In, and selenium Se and/or sulfur S chalcopyrite. It can, for example, be a material of the CuInSe₂ type. This type of material is known under the abbreviation CIS. It can also be CIGS, that is to say a material additionally incorporating gallium.

For this type of application, the electrodes are generally based on molybdenum (Mo) as this material exhibits a number of advantages. It is a good electrical conductor (relatively low specific resistance of the order of 10 μΩ·cm). It can be subjected to the necessary high heat treatments as it has a high melting point (2610° C.). It withstands well, to a certain extent, selenium and sulfur. The deposition of the layer of absorbing agent generally requires contact with an atmosphere comprising selenium or sulfur, which tends to damage the majority of metals. Molybdenum reacts at the surface, with selenium in particular, forming MoSe₂, but keeps the bulk of its properties, in particular electrical properties, and retains an appropriate electrical contact with the CIS or CIGS layer. Finally, it is a material to which the layers of CIS or CIGS type adhere well; the molybdenum even tends to promote the crystal growth thereof.

However, molybdenum exhibits a major disadvantage when industrial production is envisaged: it is an expensive material. This is because the molybdenum layers are normally deposited by cathode sputtering (magnetic-field-assisted). In point of fact, molybdenum targets are expensive. This is all the more important as, in order to obtain the desired level of electrical conductivity (a resistance per square of less than or equal to 2 Ω/□ and preferably of less than or equal to 1 or 0.5 Ω/□, after treatment in an atmosphere containing S or Se), a relatively thick layer of Mo, generally of the order of from 700 nm to 1 micrometer, is necessary.

Patent application WO-A-02/065554 from Saint-Gobain Glass France teaches the provision of a relatively thin layer of molybdenum (less than 500 nm) and the provision of one or more layers impermeable to alkali between the substrate and the molybdenum-based layer, so as to retain the qualities of the thin molybdenum-based layer during the subsequent heat treatments.

Nevertheless, this type of conducting substrate remains relatively expensive.

One aim of the present invention is to provide a novel molybdenum-based conducting substrate, the manufacturing cost of which is relatively low.

To this end, a subject-matter of the present invention is a conducting substrate for a photovoltaic cell, comprising:
a dielectric substrate comprising alkali ions;
an electrode coating formed on the substrate, the electrode coating comprising a molybdenum-based layer, the conducting substrate comprising a stack of several layers formed on the substrate and interposed between the substrate and the electrode coating, including:
   a first layer impermeable to alkali (i.e., to alkali ions) formed on the substrate;
   a layer for retention of alkali, the layer for retention of alkali (i.e., alkali ions) being formed on the first layer impermeable to alkali and made of a material other than the first layer impermeable to alkali, the ratio of the thickness of the layer for retention of alkali to the first layer impermeable to alkali being equal to 2 or more;
   a second layer impermeable to alkali (i.e., to alkali ions), the second layer impermeable to alkali being formed on the layer for retention of alkali and made of a material other than the layer for retention of alkali.

Such a stack makes it possible to provide an effective barrier to alkali (i.e., to alkali ions) during the heat treatments undergone by the conducting substrate, in particular during the deposition of the chalcopyrite-based absorbing agent.

This is because it has turned out that some materials prevent alkali from migrating towards the upper layers for two different reasons.

It has been found that some materials, which will be referred to as “impermeable to alkali”, are difficult to penetrate by alkali metal ions and for this reason prevent the migration of the alkali towards the upper layers. Other materials, referred to here as “for retention of alkali”, for their part act in the storing of alkali ions and also prevent the migration of alkali towards the upper layers.

The stack cleverly combines impermeable layer and retention layer by placing a retention layer between two impermeable layers. For this reason, if the alkali ions pass through the first impermeable layer, they will be largely trapped in the retention layer, in particular because the second impermeable layer greatly restricts the possibilities for the alkali ions of exiting from the retention layer.

In contrast to a stack optimized for an optical purpose, as in WO-A-02/065554, which uses an Si₃N₄/SiO₂/Si₃N₄ stack for this purpose, the layers are not chosen here to have the same thicknesses.

The retention layer of the stack has a thickness at least twice that of the impermeable layer on which it is deposited. This is because it has turned out that substantially only the thickness of the retention layer has a significantly positive effect on the barrier properties to alkali of the stack. The stack is thus particularly well suited to preventing alkali ions from migrating towards the upper layers, this being achieved for a relatively low cost.

By virtue of the action of the stack, the migration of the alkali from the substrate is greatly restricted and the qualities of the molybdenum-based layer are retained.

As there is no risk of the molybdenum-based layer being damaged by the action of the alkali ions, it is thus possible to provide a thin molybdenum-based layer, for example of approximately 30 nm. The cost of the electrode coating can thus be relatively low.

In addition, as explained in WO-A-02/065554, to reduce the thickness of the molybdenum layer exhibits another advantage: of making it possible to deposit these relatively thin layers by cathode sputtering with deposition parameters resulting in highly stressed layers, without the problems of delamination which can be encountered with thick layers. Thin layers in addition tend to exhibit fewer defects known under the term of pinholes.

To provide such a stacking makes it possible in addition to use, as substrate, a sheet of glass of soda-lime-silica type obtained by the float process, glass which is relatively cheap and which exhibits all the qualities which are known for this type of material, such as, for example, its transparency, its impermeability to water and its hardness.

According to specific embodiments, the above device additionally comprises one or more of the following technical characteristics, taken in isolation or according to all the technically possible combinations:
the ratio of the thickness of the layer for retention of alkali to the first layer impermeable to alkali is equal to 3 or more;
the first layer impermeable to alkali has a thickness of greater than or equal to 3 nm, for example of greater than or equal to 5 nm;
the first layer impermeable to alkali has a thickness of less than or equal to 30 nm, for example of less than or equal to 20 nm, for example of less than or equal to 15 nm;
the layer for retention of alkali has a thickness of greater than or equal to 20 nm, for example of greater than or equal to 25 nm;
the layer for retention of alkali has a thickness of less than or equal to 60 nm, for example of less than or equal to 40 nm, for example of less than or equal to 35 nm;
the layer for retention of alkali is in contact with the first layer impermeable to alkali;
the ratio of the thickness of the layer for retention of alkali to the second layer impermeable to alkali is equal to 2 or more, for example equal to 3 or more;
the second layer impermeable to alkali has a thickness of greater than or equal to 3 nm, for example of greater than or equal to 5 nm;
the second layer impermeable to alkali has a thickness of less than or equal to 30 nm, for example of less than or equal to 20 nm, for example of less than or equal to 15 nm;
the second layer impermeable to alkali is in contact with the layer for retention of alkali;
the first layer impermeable to alkali and the second layer impermeable to alkali are made of one and the same material;
said stack comprises only the first layer impermeable to alkali, the layer for retention of alkali and the second layer impermeable to alkali;
said stack comprising a second layer for retention of alkali formed on the second layer impermeable to alkali, said stack comprising a third layer impermeable to alkali formed on the second layer for retention of alkali;
the ratio of the thickness of the second layer for retention of alkali to the second layer impermeable to alkali is equal to 2 or more, for example equal to 3 or more;
the ratio of the thickness of the second layer for retention of alkali to the third layer impermeable to alkali is equal to 2 or more, for example equal to 3 or more;
each layer impermeable to alkali is based on silicon nitride;
the or each layer for retention of alkali is based on silicon oxide or based on tin oxide, for example a mixed oxide of tin and zinc;
the molybdenum-based layer has a thickness of at least 20 nm, for example of at least 50 or 80 nm;
the molybdenum Mo-based layer has a thickness of at most 500 nm, for example of at most 400 nm, for example of at most 300 nm or for example of at most 200 nm.

Another subject matter of the invention is a semiconducting device comprising a conducting substrate as described above and a layer of a light-absorbing agent, for example based on chalcopyrite, the layer being formed on the conducting substrate.

A further subject matter of the invention is a photovoltaic cell comprising a semiconducting device as described above.

A further subject matter of the invention is a process for the manufacture of a conducting substrate comprising stages consisting in:
forming a first layer impermeable to alkali on a dielectric substrate comprising alkali;
forming a layer for retention of alkali on the first layer impermeable to alkali, the ratio of the thickness of the layer for retention of alkali to the first layer impermeable to alkali being equal to 2 or more and the layer for retention of alkali being made of a material other than the first layer impermeable to alkali;
forming a second layer impermeable to alkali on the layer for retention of alkali and made of a material other than the layer for retention of alkali;
forming an electrode coating comprising a molybdenum-based layer on the second layer impermeable to alkali.

According to specific embodiments, the above process additionally comprises one or more of the following technical characteristics, taken in isolation or according to all the technically possible combinations:
the ratio of the thickness of the layer for retention of alkali to the first layer impermeable to alkali is equal to 3 or more;
the first layer impermeable to alkali has a thickness of greater than or equal to 3 nm, for example of greater than or equal to 5 nm;
the first layer impermeable to alkali has a thickness of less than or equal to 30 nm, for example of less than or equal to 20 nm, for example of less than or equal to 15 nm;
the layer for retention of alkali has a thickness of greater than or equal to 20 nm, for example of greater than or equal to 25 nm;
the layer for retention of alkali has a thickness of less than or equal to 60 nm, for example of less than or equal to 40 nm, for example of less than or equal to 35 nm;
the layer for retention of alkali is formed directly on the first layer impermeable to alkali;
the ratio of the thickness of the layer for retention of alkali to the second layer impermeable to alkali is equal to 2 or more, for example equal to 3 or more;
the second layer impermeable to alkali has a thickness of greater than or equal to 3 nm, for example of greater than or equal to 5 nm;
the second layer impermeable to alkali has a thickness of less than or equal to 30 nm, for example of less than or equal to 20 nm, for example of less than or equal to 15 nm;
the second layer impermeable to alkali is formed directly on the layer for retention of alkali;
the first layer impermeable to alkali and the second layer impermeable to alkali are made of one and the same material;
only the first layer impermeable to alkali, the layer for retention of alkali and the second layer impermeable to alkali are formed on the substrate before the formation of the electrode coating, indeed even before the formation of the molybdenum-based layer;
the process comprises a stage consisting in forming a second layer for retention of alkali on the second layer impermeable to alkali and a stage consisting in forming a third layer impermeable to alkali on the second layer for retention of alkali;
the ratio of the thickness of the second layer for retention of alkali to the second layer impermeable to alkali is equal to 2 or more, for example equal to 3 or more;
the ratio of the thickness of the second layer for retention of alkali to the third layer impermeable to alkali is equal to 2 or more, for example equal to 3 or more;
each layer impermeable to alkali is based on silicon nitride;
the or each layer for retention of alkali is based on silicon oxide or based on tin oxide, for example a mixed oxide of tin and zinc;
the molybdenum-based layer has a thickness of at least 20 nm, for example of at least 50 or 80 nm;
the molybdenum Mo-based layer has a thickness of at most 500 nm, for example of at most 400 nm, for example of at most 300 nm or for example of at most 200 nm.

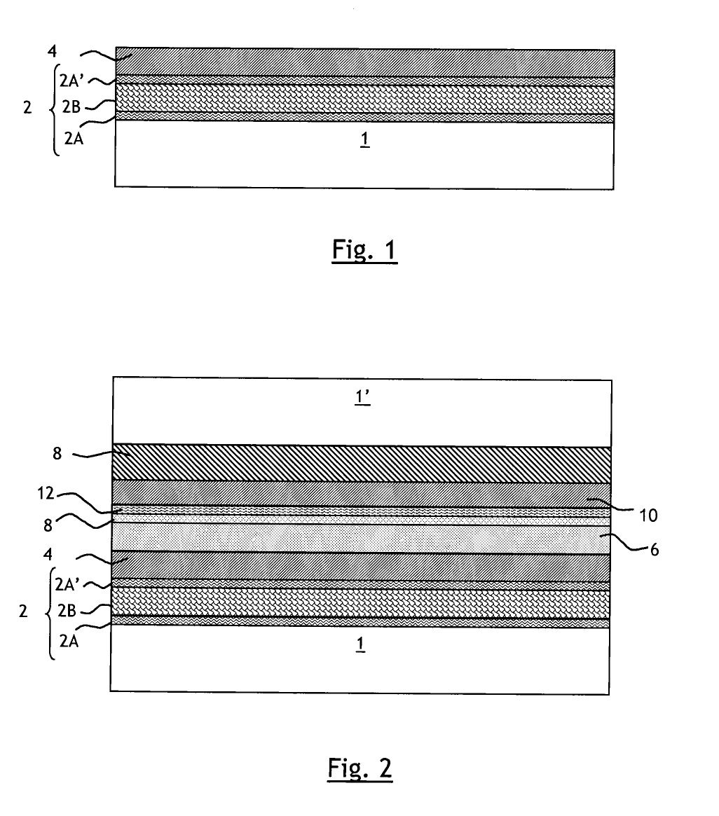

A better understanding of the invention will be obtained on reading the description which will follow, given solely by way of example, and with reference to the appended drawings, in which FIG. 1 is a diagrammatic view in cross section of a conducting substrate and FIG. 2 is an analogous view illustrating a photovoltaic cell comprising the conducting substrate of FIG. 1.

The drawings are not to scale, for clear representation, as the differences in thickness between in particular the substrate and the layers deposited are large, for example of the order of a factor of 500.

A conducting substrate for a photovoltaic cell is illustrated in FIG. 1, which conducting substrate comprises:
a dielectric substrate 1 made of glass;
a barrier stack to alkali 2 formed on the substrate 1; and
a molybdenum-based electrode coating 4 formed on the barrier stack to alkali 2.

The term “a layer A formed (or deposited) on a layer B” is understood to mean, throughout the text, a layer A formed either directly on the layer B and thus in contact with the layer B or formed on the layer B with interposition of one or more layers between the layer A and the layer B.

In addition, throughout the text, the term “comprises a” should, of course, be understood as “comprises at least one”.

The barrier stack to alkali 2 illustrated comprises three layers only:
a first layer impermeable to alkali 2A formed directly on the glass substrate 1;
a layer for retention of alkali 2B formed directly on the first layer impermeable to alkali 2A;
a second layer impermeable to alkali 2A′ formed directly on the layer for retention of alkali 2B.

Nevertheless, in an alternative form, the barrier stack to alkali 2 comprises more than three layers, for example an odd number of layers, the stack preferably alternating layer impermeable to alkali and layer for retention of alkali.

In another alternative form, the first impermeable layer 2A is not deposited directly on the glass substrate 1.

In addition, it should be noted that other layers can be intercalated in the barrier stack to alkali.

Thus, generally, the barrier stack to alkali 2 comprises:
a first layer impermeable to alkali 2A formed on the substrate 1;
a layer for retention of alkali 2B formed on the first layer impermeable to alkali 2A, for example directly on the first layer impermeable to alkali 2A;
a second layer impermeable to alkali 2A′ formed on the layer for retention of alkali 2A′, for example directly on the layer for retention of alkali 2B.

Throughout the text, “comprises a layer” should be understood as “comprises at least one layer”.

The layer for retention of alkali 2B is formed of a material other than the first layer impermeable to alkali 2A. In addition, the ratio of the thickness of the layer for retention of alkali 2B to the first layer impermeable to alkali 2A is equal to 2 or more, for example equal to 3 or more.

The term “layer impermeable to alkali” is understood to mean, throughout the text, a layer composed of a material impermeable to alkali, that is to say a material which is difficult for alkali metal ions to penetrate, and the term “layer for retention of alkali” is understood to mean a layer composed of a material for retention of alkali, namely a material having an ability to retain alkali ions within the material.

Two tests are laid down here to describe these materials.

Test of Material Impermeable to Alkali and of Material for Retention of Alkali:

A glass substrate with a minimum thickness of 2 mm, the concentration by weight of sodium ions of which, denoted Cglass, is at least 5%, is used. The test material is deposited directly on the substrate as a layer of this material with a thickness of 100 nm.

The combination is subsequently annealed at 600° C. under air for 30 min at a pressure of approximately 1 atm.

After the annealing, the concentration by weight of sodium ions is measured at a depth of 50 nm in the layer by the SIMS (Secondary Ion Mass Spectroscopy) method. It is denoted C50. This concentration is also measured on a control sample before annealing for the test of the retention material, and is also denoted C50.

The test of material impermeable to alkali is successful if C50/Cglass≦0.001 after the annealing.

The test of material for retention of alkali is successful if C50/Cglass≦0.001 before the annealing and C50/Cglass≧0.3 after the annealing.

The SIMS measurements are, for example, carried out with the following parameters in order to determine the concentrations of sodium ions:
abrasion with Cs atoms (energy=3 keV)
analysis with Ga atoms (energy=15 keV).

The above measurement method is provided by way of example. In an alternative form, the analysis of the concentration by weight of sodium ions is of any suitable type.

A material impermeable to alkali is, for example, made of silicon nitride or made of aluminum nitride.

A material for retention of alkali is, for example, made of silicon oxide or made of tin oxide or made of a mixed oxide of tin and zinc, the zinc oxide then being a minor component.

It should be noted that the above nitrides and oxides can be sub-stoichiometric, stoichiometric or superstoichiometric respectively in nitrogen and in oxygen.

The layer for retention of alkali and/or the layer impermeable to alkali is, for example, doped with a metal, for example with aluminum, particularly in the case of magnetron deposition of the layer.

The same materials will, for example, be used respectively for all the layers impermeable to alkali and for all the layers for retention of alkali of the barrier stack to alkali.

The first layer impermeable to alkali 2A has, for example, a thickness of greater than or equal to 3 nm, for example of greater than or equal to 5 nm, and has, for example, a thickness of less than or equal to 30 nm, for example of less than or equal to 20 nm, for example of less than or equal to 15 nm.

The layer for retention of alkali 2B has, for example, a thickness of greater than or equal to 20 nm, for example of greater than or equal to 25 nm, and for example a thickness of less than or equal to 60 nm, for example of less than or equal to 40 nm, for example of less than or equal to 35 nm.

The second layer impermeable to alkali 2A′ has, for example, a thickness of greater than or equal to 3 nm, for example of greater than or equal to 5 nm, and has, for example, a thickness of less than or equal to 30 nm, for example of less than or equal to 20 nm, for example of less than or equal to 15 nm.

In an alternative form, the barrier stack to alkali comprises at least two additional layers, namely a second layer for retention of alkali formed on the second layer impermeable to alkali, for example directly above, and a third layer impermeable to alkali formed on the second layer for retention of alkali, for example directly above.

The second layer for retention of alkali has, for example, a thickness of greater than or equal to 20 nm, for example of greater than or equal to 25 nm, and a thickness of less than or equal to 60 nm, for example of less than or equal to 40 nm, for example of less than or equal to 35 nm.

The third layer impermeable to alkali has, for example, a thickness of greater than or equal to 3 nm, for example of greater than or equal to 5 nm, and has, for example, a thickness of less than or equal to 30 nm, for example of less than or equal to 20 nm, for example of less than or equal to 15 nm.

The remainder of the conducting substrate will now be described.

The electrode coating 4 is particular in that it comprises at least one molybdenum-based layer. It is, for example, an electrode coating as described in WO-A-02/065554.

It should be noted that, throughout the text, the term “electrode coating” is understood to mean a current-conveying coating comprising at least one layer which conducts electrons, that is to say having a conductivity which is provided by the mobility of the electrons.

Throughout the text, the term “molybdenum-based” is understood to mean a material composed of a substantial amount of molybdenum, that is to say either a material composed solely of molybdenum (and thus a metal), or a metallic alloy predominantly comprising molybdenum, or a compound based on molybdenum, for example a molybdenum disulfide, a molybdenum diselenide, a molybdenum disulfide and diselenide compound Mo(S,Se)₂, or a molybdenum oxide, nitride or oxynitride Mo(O,N).

Conventionally, the notation (S, Se) indicates that this concerns a combination of SₓSe₁₋ₓ with 0≦x≦1.

By way of example, the electrode coating 4 comprises, for example, just one layer, as illustrated in FIGS. 1 and 2, which layer is made of molybdenum and has a thickness of between 300 nm and 500 nm, for example of between 300 nm and 450 nm.

Throughout the text, the term “just one layer” is understood to mean a layer made of one and the same material. This single layer can nevertheless be obtained by the superimposition of several layers of one and the same material, between which exists an interface which it is possible to characterize, as described in WO-A-2009/080931.

Typically, in a magnetron deposition chamber, several layers of one and the same material will be successively formed on the dielectric substrate by several targets in order to form, in the end, just one layer of the same material, namely molybdenum.

In an alternative form, in the case where the electrode coating 4 comprises several electrically conducting layers, the upper layer of the coating 4 is, for example, a layer of molybdenum, so as to provide the electrode coating 4 with resistance to selenization. The upper layer made of molybdenum can then be thin, for example with a thickness of less than or equal to 50 nm.

The conducting substrate formed by the dielectric substrate 1, the barrier stack to alkali 2 and the electrode coating 4 is intended to be at the rear of the photoactive layer with respect to the light source, that is to say to receive the incident light after the photoactive layer. It is thus a “rear” conducting substrate.

The dielectric substrate 1 is, for example, a sheet having a window function. However, in an alternative form, it is not transparent.

The sheet can be flat or convex and can exhibit dimensions of any type, in particular at least one dimension of greater than 1 meter.

It is advantageously a glass sheet.

The glass can be clear or extra-clear or can alternatively be tinted, for example in blue, green, amber, bronze or gray.

The thickness of the glass sheet is typically between 0.5 and 19 mm, particularly between 2 and 12 mm, indeed even between 4 and 8 mm. It can also be a glass film with a thickness of greater than or equal to 50 μm (in this case, the barrier stack and the electrode coating are deposited, for example, by a roll-to-roll process).

Generally, the substrate is of any appropriate type and comprises alkali, for example sodium and/or potassium ions. The substrate is, for example, a soda-lime-silica glass.

A glass of soda-lime-silica type can be obtained by the float glass process. It is thus a glass with a relatively low cost which exhibits all the qualities which are known for this type of material, such as, for example, its transparency, its impermeability to water and its hardness.

The term “glass of soda-lime-silica type” is understood to mean a glass comprising, in its composition, silica (SiO₂) as former oxide and oxides of sodium (soda Na₂O) and calcium (lime CaO). This composition preferably comprises the following constituents in a content varying within the limits by weight defined below:

SiO₂ 60-75%

Al₂O₃ 0-10%

B₂O₃ 0-5%, preferably 0

CaO 5-15%

MgO 0-10%

Na₂O 5-20%

K₂O 0-10%

BaO 0-5%, preferably 0.

In an alternative form, it is not a soda-lime-silica glass.

Generally, the dielectric substrate is made of a silica-based glass, the composition of the constituents of which exhibits at least 5% by weight of Na₂O.

Another subject matter of the invention is a process for the manufacture of the conducting substrate described above.

The process comprises stages consisting in:
forming the first layer impermeable to alkali 2A on the dielectric substrate 1;
forming the layer for retention of alkali 2B on the first layer impermeable to alkali 2A, for example directly above, the ratio of the thickness of the layer for retention of alkali 2B to the first layer impermeable to alkali 2A being equal to 2 or more and the layer for retention of alkali 2B being made of a material other than the first layer impermeable to alkali 2A;
forming the second layer impermeable to alkali 2A′ on the layer for retention of alkali 2B, for example directly above, and made of a material other than the layer for retention of alkali 2B;
forming the electrode coating 4 comprising a molybdenum-based layer on the second layer impermeable to alkali, for example directly above.

Another subject matter of the invention is a semiconducting device comprising a conducting substrate as described above and a layer of a light-absorbing agent, for example based on chalcopyrite, formed on the conducting substrate.

It is, for example, a layer of copper Cu, indium In, and selenium Se and/or sulfur S chalcopyrite. It can, for example, be a material of the CuInSe₂ (CIS) type. It can also be a material additionally incorporating gallium (CIGS).

Generally, it is a layer of an absorbing agent formed by addition of alkali ions prior to or during the deposition of the absorbing agent on the conducting substrate. U.S. Pat. No. 5,626,688 describes a process of this type.

Such a process, in combination with the presence of a barrier stack to alkali preventing the diffusion of the alkali ions towards the absorbing agent, exhibits the advantage of making possible precise metering of the addition of the alkali ions to the layer of absorbing agent.

Another subject matter of the invention is a photovoltaic cell comprising a semiconducting device as described above. The conducting substrate is intended to be at the rear of the photoactive layer with respect to the light source, that is to say to be traversed by the incident light after the photoactive layer.

The cell comprises, for example, as illustrated in FIG. 2:
a conducting substrate as described above;
a doped layer 6 of p type of Cu(In,Ga)Se₂ formed directly on the electrode coating 4 comprising a molybdenum-based layer;
a doped layer 8 of n type, referred to as buffer, for example composed of CdS, formed on the layer of Cu(In,Ga)Se₂;
a transparent electrode coating 10, for example of ZnO:Al, with optional interposition, between the transparent electrode coating 10 and the buffer layer, of a passivating layer 12, for example of intrinsic ZnO.

However, it should be noted that, in an alternative form, the cell does not comprise a buffer layer, it being possible for the layer of Cu(In,Ga)Se₂ to itself form a p-n homojunction.

In another alternative form, the layer of light-absorbing agent is a layer based on kesterite or stannite of formula Cu₂(Sn,Zn)(S,Se)₄ or a layer based on chalcopyrite not necessarily formed by the selenization alone of the metal compounds but also, for example, by a sulfurization, such as a layer of Cu_{y}(In,Ga)(S,Se)₂ type.

Generally, the layer of p type or comprising a p-n homojunction is a photoactive layer obtained by addition of alkali elements.

In an alternative form, the buffer layer 16 is, for example, based on InₓS_{y}, Zn(O,S) or ZnMgO.

The transparent electrode coating 18 comprises, in an alternative form, a layer of zinc oxide doped with gallium, or boron, or an ITO layer.

Generally, it is a transparent conducting material (TCO) of any suitable type.

For a good electrical connection and good conductance, a metal grid is subsequently optionally deposited on the transparent electrode coating 10, for example through a mask, for example by an electron beam (not represented in FIG. 2). It is, for example, an Al (aluminum) grid, for example with a thickness of approximately 2 μm, on which is deposited an Ni (nickel) grid, for example with a thickness of approximately 50 nm, in order to protect the Al layer.

The cell is subsequently protected. It comprises, for example, to this end, a counter-substrate 1′, as illustrated, covering the front electrode coating 10 and laminated to the substrate 1 via a lamination interlayer 14 made of thermosetting plastic. It is, for example, a lamination interlayer made of EVA, PU or PVB.

Another subject matter of the invention is a process for the manufacture of the semiconducting device and of the photovoltaic cell above, which process comprises a stage of formation of a light-absorbing agent the electrode coating 4.

The stage of formation of the light-absorbing agent comprises a stage of selenization and/or sulfurization carried out in an atmosphere comprising a selenium- and/or sulfur-based gas and at a temperature of greater than 300° C.

The layer of absorbing agent is, for example, a layer of CIGS formed in the following way.

A metal stack based on Cu, In and Ga is, for example, deposited by sputtering at ambient temperature on the electrode coating 6 and then selenized in a selenium-based atmosphere at high temperature, for example at approximately 600° C.

The alkali ions were, for example, introduced beforehand by deposition, on the electrode coating 4, of a layer of sodium selenide (Na₂Se), so as to introduce, for example, of the order of 2×10¹⁵ sodium atoms per cm².

The metal stack is deposited on this layer of sodium selenide.

The metal stack has, for example, a multilayer structure of Cu/In/Ga/Cu/In/Ga . . . type. However, it is, in an alternative form, a bilayer structure of Cu—Ga/In alloy type or a structure comprising three layers of Cu/In/Ga type.

A selenium layer is subsequently, for example, deposited on the metal stack by thermal evaporation.

The metal stack is subsequently heated at at least 300° C., for example at least 400° C., for example at 600° C., in an atmosphere composed, for example, of gaseous sulfur, for example based on S or H₂S, thus forming a layer of Cu(In,Ga)(S,Se)₂.

In an alternative form, the selenization is obtained without the deposition of a layer of selenium but by an atmosphere comprising gaseous selenium, for example based on Se or H₂Se, prior to the exposure to an atmosphere rich in sulfur.

The sulfurization stage makes it possible to optionally do without the buffer layer, for example of CdS.

1. A conducting substrate, comprising:
a dielectric substrate comprising alkali ions;
an electrode coating comprising a molybdenum-based layer on the dielectric substrate, and
a stack on the substrate and between the dielectric substrate and the electrode coating,
wherein the stack comprises a first layer impermeable to alkali on the dielectric substrate;
the stack further comprises a layer suitable for retention of alkali on the first layer impermeable to alkali and comprising a material other than a material of the first layer impermeable to alkali;
a ratio of a thickness of the layer suitable for retention of alkali to a thickness of the first layer impermeable to alkali is 2 or more; and
the stack further comprises a second layer impermeable to alkali on the layer suitable for retention of alkali and comprising a material other than a material of the layer suitable for retention of alkali.

2. The conducting substrate of claim 1, wherein the ratio of the thickness of the layer suitable for retention of alkali to the thickness of the first layer impermeable to alkali is 3 or more.

3. The conducting substrate of claim 1, wherein the first layer impermeable to alkali has a thickness of less than or equal to 30 nm.

4. The conducting substrate of claim 1, wherein the layer suitable for retention of alkali has a thickness of less than 30 or equal to 60 nm.

5. The conducting substrate of claim 1, wherein a ratio of the thickness of the layer suitable for retention of alkali to a thickness of the second layer impermeable to alkali is 2 or more.

6. The conducting substrate of claim 1, wherein the second layer impermeable to alkali has a thickness of less than or equal to 30 nm.

7. The conducting substrate of claim 1, wherein the first layer impermeable to alkali and the second layer impermeable to alkali comprise the same material.

8. The conducting substrate of claim 1, wherein the first and second layers impermeable to alkali comprise silicon nitride or aluminum nitride.

9. The conducting substrate of claim 1, wherein the layer suitable for retention of alkali comprises silicon oxide, tin oxide, or a mixed oxide of tin and zinc.

10. A semiconducting device comprising the conducting substrate of claim 1 and a layer of a light-absorbing agent on the conducting substrate.

11. A photovoltaic cell comprising the semiconducting device of claim 10.

12. A process of manufacturing a conducting substrate, the process comprising:
forming a first layer impermeable to alkali on a dielectric substrate comprising alkali;
forming a layer suitable for retention of alkali comprising a material other than a material of the first layer impermeable to alkali on the first layer impermeable to alkali, with a ratio of a thickness of the layer suitable for retention of alkali to a thickness of the first layer impermeable to alkali of 2 or more;
forming a second layer impermeable to alkali comprising a material other than a material of the layer suitable for retention of alkali on the layer suitable for retention of alkali;
forming an electrode coating comprising a molybdenum-based layer on the second layer impermeable to alkali.

13. The device of claim 10, wherein the light-absorbing agent comprises chalcopyrite.
